(19) United States
(12) Patent Application Publication
(10) Pub. No.: US 2024/0311197 A1
(43) Pub. Date: Sep. 19, 2024

(54) METHOD AND SYSTEM FOR DESIGNING AND VERIFYING SYSTEM ENGINEERING BASED ON FISHBONE MODEL

(71) Applicant: 38TH RESEARCH INSTITUTE, CHINA ELECTRONICS TECHNOLOGY GROUP CORPORATION, Hefei (CN)

(72) Inventors: Jizhou FENG, Hefei (CN); Liang WU, Hefei (CN); Hongli ZHAO, Hefei (CN); Xueya YANG, Hefei (CN); Shiyou DONG, Hefei (CN); Junqing NIU, Hefei (CN)

(21) Appl. No.: 18/672,647

(22) Filed: May 23, 2024

Related U.S. Application Data
(63) Continuation of application No. PCT/CN2023/083076, filed on Mar. 22, 2023.

(30) Foreign Application Priority Data
Mar. 29, 2022 (CN) 202210318439.3

(51) Int. Cl. G06F 9/50; G06F 30/20

(52) U.S. Cl. CPC G06F 9/5038; G06F 30/20; G06F 2209/5021

(57) ABSTRACT

A method for designing and verifying system engineering based on fishbone model is provided. System-level static information, system-task-level static information, and system-task-level dynamic data flow are acquired. Based on fishbone diagram, the system-level static information is represented as a system static composite structure diagram, and the system-task-level static information is represented as a system task composite structure diagram. Based on the fishbone diagram, the system-task-level dynamic data flow is represented as a system function point dynamic data flow diagram. Based on the system task composite structure diagram and the system function point dynamic data flow diagram, a static set and a dynamic set of software function modules of the system are established, and consistency adjustment is performed between the software function modules in the static set and the dynamic set. A designing and verifying system is further provided.

### CROSS-REFERENCE TO RELATED APPLICATIONS

This application is a continuation of International Patent Application No. PCT/CN2023/083076, filed on Mar. 22, 2023, which claims the benefit of priority from Chinese Patent Application No. 202210318439.3, filed on Mar. 29, 2022. The content of the aforementioned application, including any intervening amendments thereto, is incorporated herein by reference in its entirety.

### TECHNICAL FIELD

This application relates to system engineering, and more particularly to a method and system for designing and verifying a system engineering based on fishbone model.

### BACKGROUND

Traditional systems engineering (TSE) is becoming increasingly difficult to cope with more complex engineering systems nowadays. In TSE, the system engineering activities output a series of documents based on natural language, such as user requirements and design solutions. This document is in “text format”, so the traditional systems engineering is “text-based systems engineering”. In this mode, it is time-consuming, laborious, and error-prone to integrate and link the information of engineering systems scattered in various demonstration reports, design reports, analysis reports and test reports. Moreover, with the development of information technology, the complexity and scale of modern systems increase continuously, and the traditional document-centered systems engineering has become increasingly unable to meet the needs of engineering due to the inability to ensure data consistency, difficulty in making changes, and difficulty in describing activities.

At the same time, the information technology represented by modeling is also developing rapidly, under the draught of requirements and impulse of technologies, Model-Based Systems Engineering (MBSE) emerges, which puts the model in the center of the whole engineering process and realizes the system design of the product through continuous evolution and iterative increment of model from the requirement stage. Compared to the traditional document-centered systems engineering, MBSE has many advantages, including enhanced communication between investors and team members, improved knowledge acquisition, better information traceability, enhanced reuse of artifacts, and reduced development risk. According to the International Council of Systems Engineering (INCOSE), the model-driven systems design approach “is expected to replace the document-centered approach widely used by systems engineers for many years, and eventually to be fully integrated into the systems engineering process”.

The model-based systems engineering methods simplify complex problems by describing one aspect of the problem, achieving dimensionality reduction. The model-based systems engineering methods give a clear, comprehensive description of complex problems by “linking” models from multiple perspectives. The model-based systems engineering methods ignore unimportant details to reveal the essence of the problem. The model-based systems engineering methods express the problem in a form that is easier to observe and understand, and enhances knowledge acquisition, analytical strength, and completeness. The model-based systems engineering methods realize the capture of knowledge and the maintenance of linkage information through the establishment of multi-perspective models. Thus, the model-based systems engineering methods solve the problems of insufficient knowledge management capability and insufficient auxiliary decision-making role of the document-based requirements engineering method.

Currently, six MBSE methods are widely used, namely Harmony, RUP, OOSEM, MagicGrid, OPM, Arcadia, and Vitech, which adopt UML, SysML, OPL, Arcadia, and SDL system modeling languages for modeling, respectively. However, it has been proved that for complex system design, the designers need to spend a long time to learn and understand the syntax of UML, SysML, OPL, Arcadia and SDL. Due to too complex syntax, high proficiency in mastering the methodologies and tools is required for professional designers. Moreover, the limited customization capability of the modeling tools implementing the systems engineering method, the large number of graphics, and the more flexible modeling process often results in confusion and chaos for engineers when designing architectures.

Chinese patent application publication No. 101847170 A discloses an assisted design or verification method for systems engineering, including: decomposing a system layer-by-layer into smaller subsystems based on a specification or requirement of the system; and decomposing elements of the smallest functional unit; analyzing attributes contained in the elements and the corresponding values of the attributes; statistically identifying the system or subsystems, the elements and the attribute labeling, resources, resource characteristics, and structural information between them; pairing all elements two by two, defining the relationship between the paired elements, and describing the aspects of the relationship; counting the labels, resources, resource characteristics and structural information between each other of the pairs, the relationships, and the aspects; and after integrating the pairs and their relationships into components, selectively reorganizing and packaging them into combinatorial flows, and counting the labels, resources, resource characteristics, and structural information among the components, constraints as selection conditions, combinatorial flows, and their internal components. In this way, a comprehensive and complete analysis of the system is realized. This method decomposes smaller subsystems and minimum functional unit elements based on the specification or requirement of the system. The textual representation of the content may be dichotomous, so the correctness of the decomposed minimum functional unit elements cannot be guaranteed. Secondly, for the system design stage, whether the method is automated or requires the manual participation of designers, the process of decomposition, analysis and statistics is too complicated, and the reasonableness of the attributes and corresponding attribute values of the analyzed elements will be greatly reduced at the level of abstraction of the functions that can be reached at the system design stage. Moreover, such complex and frequent decomposition, analysis, statistics, one-dimensional analysis and comparison, and two-dimensional analysis and comparison, are also a great test for the operational efficiency of the system. Finally, for the method of instantiation process validation, the design factor simulation from the beginning to the end of the instantiation of the simulation execution not only increases the burden of the system operation, and more complex simulation cannot also replace and reproduce the real situation. However, the design of such complexity loses the significance of the assistance.

Chinese patent application publication No. 112560213 A discloses a system modeling method and system based on model system engineering and hyper network theory which includes an application scenario determining module, an architecture determining module, an architecture validation module, an index determining module, a weight determining module, a central control module, an architecture model correction module, a data acquisition module, a data processing module, a data citation module, a system model output module, and a model conversion output module. The system modeling method converts the constructed system model group into a hypernetwork model, analyzes the system model mapping relationship between various perspectives, combines the generated system hypernetwork model group, and ultimately generates a multilayer hypernetwork model of the system architecture. The system modeling method is convenient to quantitatively analyze the indexes of the architecture using mathematical tools, and can guarantee the completeness and validity of the combed data through the top-to-bottom sorting and the bottom-to-top integration. The system modeling method is targeted at specific fields. When using this method, the input of the system is to establish application scenarios, however, the way of establishing application scenarios and what elements need to be given are not given specific definitions, which is difficult for implementers and users to understand and use, resulting in confusion and errors in operational information. Secondly, it is necessary to establish a scenario library and an architecture model library and understand the attributes and quantities of the corresponding architecture model, so the establishment of the two libraries requires a lot of specialized work and is not very universal.

### SUMMARY

An object of this application is to provide a simple and accurate method and system for designing and verifying a system engineering based on fishbone model.

Technical solutions of this application are described as follows.

In a first aspect, this application provides a method for designing and verifying a system engineering based on fishbone model, comprising:
acquiring modeling information, wherein the modeling information comprises system-level static information, system-task-level static information, and system-task-level dynamic data flow;
based on fishbone diagram analysis, representing the system-level static information as a system static composite structure diagram, and representing the system-task-level static information as a system task composite structure diagram corresponding to each system task in the system static composite structure diagram;
based on the fishbone diagram analysis, representing the system-task-level dynamic data flow as a system function point dynamic data flow diagram;
based on the system task composite structure diagram, establishing a static set of first software function modules of a system; and based on the system function point dynamic data flow diagram, establishing a dynamic set of second software function modules of the system; and
performing a consistency adjustment between the first software function modules in the static set and the second software function modules in the dynamic set to make the first software function modules in the static set consistent with the second software function modules in the dynamic set.

In an embodiment, the system-level static information comprises a system name primitive and a system task name primitive;
the system-task-level static information comprises the system task name primitive and a software function module name primitive; and
the system-task-level dynamic data flow comprises the system task name primitive, a software name primitive, and the software function module name primitive.

In an embodiment, the step of “based on fishbone diagram analysis, representing the system-level static information as a system static composite structure diagram, and representing the system-task-level static information as a system task composite structure diagram corresponding to each system task in the system static composite structure diagram” comprises:
placing the system name primitive at an endpoint of a transverse straight line in a first fishbone diagram as a fishbone head, and placing the system task name primitive on an oblique line of the first fishbone diagram, so as to form the system static composite structure diagram; and
for a system task in the system static composite structure diagram, placing the system task name primitive at an endpoint of a transverse straight line in a second fishbone diagram as a fishbone head, and placing the software function module name primitive for performing the system task on an oblique line of the second fishbone diagram, so as to form the system task composite structure diagram.

In an embodiment, the step of “based on the fishbone diagram analysis, representing the system-task-level dynamic data flow as a system function point dynamic data flow diagram” comprises:
representing a system task by an arrowed transverse straight line; and placing a system task name primitive at an endpoint of a transverse straight line in a first fishbone diagram as a fishbone head;
placing a software name primitive on an oblique line in the first fishbone diagram; and
placing a software function module name primitive on an oblique line in a second fishbone diagram in which the software name primitive is taken as the fishbone head.

In an embodiment, an order of the system task name primitive, the software name primitive, and the software function module name primitive is consistent with an execution order of the system; and
when a software or a software function module is in chronological juxtaposition, the arrowed transverse straight line connecting the software or the software function module is indicated by a dashed line.

In an embodiment, the step of “based on the system task composite structure diagram, establishing a static set of first software function modules of a system; and based on the system function point dynamic data flow diagram, establishing a dynamic set of second software function modules of the system” comprises:
establishing a static set Aₖ of the first software function modules of the system based on the system task composite structure diagram, wherein k represents the number of the first software function modules in the static set; and
establishing a dynamic set Aₙ of the second software function modules of the system based on the system function point dynamic data flow diagram, wherein n represents the number of the second software function modules in the dynamic set.

In an embodiment, the step of “performing a consistency adjustment between the first software function modules in the static set and the second software function modules in the dynamic set to make the first software function modules in the static set consistent with the second software function modules in the dynamic set” comprises:
according to a priority order of the first software function modules in the static set, determining a weight of each of the first software function modules by using a weight determination model, expressed as:

$${\sum }_{i = 1}^{k} {m}_{i} = 1 ; and$$

$${m}_{i} ∈ {A}_{k} , and {m}_{1} > {m}_{2} > … > {m}_{k} ;$$

wherein Aₖ denotes the static set; m₁, m₂ . . . , and mₖ respectively denote weights of the first software function modules in the static set; and k denotes the number of the first software function modules in the static set;
performing the consistency adjustment between the first software function modules in the static set and the second software function modules in the dynamic set based on a consistency determination model, expressed as:

$$Z = {\sum }_{i = 1}^{n} {m}_{i} ;$$

$${m}_{i} = {m}_{j}^{k} , {m}_{i} ∈ {A}_{k} , i \leq n , j \leq k ; and$$

$${m}_{i} = k , {m}_{i} ∉ {A}_{k} , i \leq n ;$$

wherein n and k are positive integers; n denotes the number of the second software function modules in the dynamic set; and mⱼ^{k} denotes a weight of a corresponding first software function module in the static set; and
when Z=1, it is determined that the first software function modules in the static set are consistent with the second software function modules in the dynamic set for system engineering level assessment.

In an embodiment, the step of “according to a priority order of the first software function modules in the static set, determining a weight of each of the first software function modules by a weight determination model” comprises:
based on a convergence principle and the priority order, determining the weight of each of the first software function modules by decreasing weights of the first software function modules in the static set in a proportion of *, expressed as:

$${m}_{1} = \frac{( k - 1 ) * {k}^{k - 1}}{{k}^{k} - 1} , i = 1 ; and$$

$${m}_{i} = {m}_{1} * \frac{1}{{k}^{i - 1}} , i \neq 1 , and i \leq k .$$

In an embodiment, when Z>1, the first software function modules in the static set or the second software function modules in the dynamic set are adjusted until Z≤1; and
when Z<1, the first software function modules in the static set or the second software function modules in the dynamic set are adjusted until Z=1.

In a second aspect, this application provides a system for designing and verifying a system engineering based on fishbone model, comprising:
an information acquisition module;
a first information representation module;
a second information representation module;
a set determination module; and
a consistency determination module;
wherein the information acquisition module is configured for acquiring modeling information, wherein the modeling information comprises system-level static information, system-task-level static information, and system-task-level dynamic data flow;
the first information representation module is configured for representing, based on fishbone diagram analysis, the system-level static information as a system static composite structure diagram, and representing the system-task-level static information as a system task composite structure diagram corresponding to each system task in the system static composite structure diagram;
the second information representation module is configured for representing the system-task-level dynamic data flow as a system function point dynamic data flow diagram based on the fishbone diagram analysis;
the set determination module is configured for establishing a static set of first software function modules of a system based on the system task composite structure diagram; and establishing a dynamic set of second software function modules of the system based on the system function point dynamic data flow diagram; and
the consistency determination module is configured for performing a consistency adjustment between the first software function modules in the static set and the second software function modules in the dynamic set to make the first software function modules in the static set consistent with the second software function modules in the dynamic set.

This application has the following beneficial effects.
(1) Compared to the problem of learning threshold of the existing MBSE methods, a fishbone model-based system engineering method in this application is easier for engineers to get started, understand and use. Moreover, the static composite diagram of the system functions based on the fishbone model, the static composite diagram of each system function and the dynamic data flow diagram of the system function points based on the fishbone model can make the structure of the system simple and clear, and can virtualize the actual system, simulate the use of scenarios, and the system and its implementation of the design of the software for effective validation, which is conducive to the early exposure and discovery of the system's design problems. By comparing the dynamic data flow of each system function based on the fishbone model with the static composite structure diagram of each system function, the integrity, consistency, and sufficient necessity of traceability between the system function and each software realizing the system task are ensured, and the verification of the system data flow is strengthened, which is conducive to the early discovery of the software problem and improve the reliability of the system effectively.

Additional aspects and advantages of this application will be given partially, and the part will become apparent from the following description or be learned through the practice of the present application.

### BRIEF DESCRIPTION OF THE DRAWINGS

FIG. 1 is a flow diagram of a method for designing and verifying a system engineering based on fishbone model according to an embodiment of the present disclosure;

FIG. 2 is a schematic diagram of a model-based system function static composite structure according to an embodiment of the present disclosure;

FIG. 3 is a schematic diagram of a static composite structure of each system function according to an embodiment of the present disclosure;

FIG. 4 is a schematic diagram of a dynamic data flow based on system function points according to an embodiment of the present disclosure;

FIG. 5 is a schematic diagram of a set of icon prescribed meanings according to an embodiment of the present disclosure;

FIG. 6 is a schematic diagram of a link communication system-level static composite structure according to an embodiment of the present disclosure;

FIG. 7 is a schematic diagram of a link communication system task static composite structure according to an embodiment of the present disclosure;

FIG. 8 is a schematic diagram of a dynamic data flow of a link communication system task according to an embodiment of the present disclosure;

FIG. 9 is a schematic diagram of a static composite structure of a parking access control system according to an embodiment of the present disclosure;

FIG. 10 is a schematic diagram of a static composite structure of a parking access control system task according to an embodiment of the present disclosure;

FIG. 11 is a schematic diagram of a dynamic data flow of the parking access control system task according to an embodiment of the present disclosure; and

FIG. 12 is a schematic diagram of a system for designing and verifying the system engineering based on fishbone model according to an embodiment of the present disclosure.

### DETAILED DESCRIPTION OF EMBODIMENTS

The technical solutions in the embodiments of the present disclosure will be clearly and completely described below in conjunction with the accompanying drawings of the present disclosure, to make the purpose, technical solutions, and advantages of the embodiments of the disclosure clearer. Described below are merely some embodiments of the disclosure, which are not intended to limit the disclosure. For those skilled in the art, other embodiments obtained based on these embodiments without paying creative efforts should fall within the scope of the disclosure.

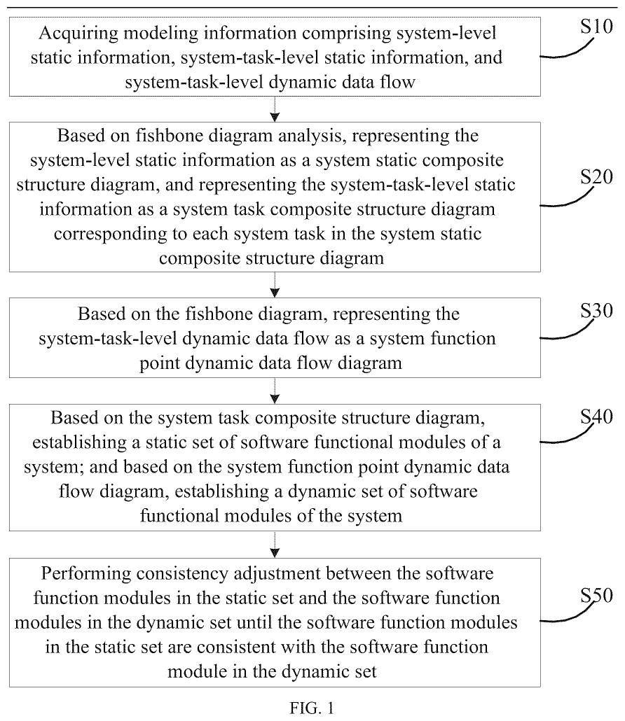

Referring to FIG. 1, in this embodiment, the method for designing and verifying a system engineering based on fishbone model includes the following steps.
(S10) Modeling information is acquired. The modeling information includes system-level static information, system-task-level static information, and system-task-level dynamic data flow.
(S20) Based on a fishbone diagram, the system-level static information is represented as a system static composite structure diagram, and the system-task-level static information is represented as a system task composite structure diagram corresponding to each system task in the system static composite structure diagram.
(S30) Based on fishbone diagram analysis, the system-task-level dynamic data flow is represented as a system function point dynamic data flow diagram.
(S40) A static set of software function modules of a system is established based on the system task composite structure diagram; and a dynamic set of the software function modules of the system is established based on the system function point dynamic data flow diagram.
(S50) A consistency adjustment is performed between the software function modules in the static set and the software function modules in the dynamic set to make the software function modules in the static set consistent with the software function modules in the dynamic set.

Compared to the problem of learning threshold of the existing MBSE methods, a fishbone model-based system engineering method in this application is easier for engineers to get started, understand and use. Moreover, the system function static composite diagram based on the fishbone model, the static composite diagram of each system function and the dynamic data flow diagram of the system function points based on the fishbone model can make the structure of the system simple and clear, and can virtualize the actual system, simulate the use of scenarios, and the system and its implementation of the design of the software for effective validation, which is conducive to the early exposure and discovery of the system's design problems. By comparing the dynamic data flow of each system function based on the fishbone model with the static composite structure diagram of each system function, the integrity, consistency, and sufficient necessity of traceability between the system function and each software realizing the system task are ensured, and the verification of the system data flow is strengthened, which is conducive to the early discovery of the software problem, and the reliability of the system can be effectively improved.

In an embodiment, in the step (S10), the system-level static information includes a system name primitive and a system task name primitive.

The system-task-level static information includes the system task name primitive and a software function module name primitive.

The system-task-level dynamic data flow includes the system task name primitive, a software name primitive, and a software function module name primitive.

It is noted that the modeling information in this embodiment may be a primitive in a self-development tool. Graphics View framework structure of Qt is used to provide the model view programming based on primitives. Graphics View framework includes three main classes, namely, QGraphicsScene class, QGraphicsView class, and QGraphItem primitive class. One scene can be represented by multiple views. One scene includes multiple geometries, and the Graphics View framework structure of Qt's defines and generates the system name primitives.

In an embodiment, the step (S20) includes the following steps.
(S21) The system name primitive is placed at the endpoint of the transverse straight line in the fishbone diagram as the fishbone head, and the system task name primitive is listed on the oblique line of the fishbone diagram, so as to form the system static composite structure diagram.
(S22) For a system task in the system static composite structure diagram, the system task name primitive is placed at the endpoint of the transverse straight line in the fishbone diagram as the fishbone head, and the software function module name primitive for realizing the system task is listed on the oblique line of the fishbone diagram, so as to form the system task composite structure diagram.

It is to be noted that the unified architecture of the information data of the composite elements of the system function and the software based on the fishbone model, may be represented. For example, the software name primitive is represented by a transverse straight line, and the software function module name primitive is represented by the oblique line connected to the transverse straight line of the software name primitive. Specifically, the modeling is as follows.

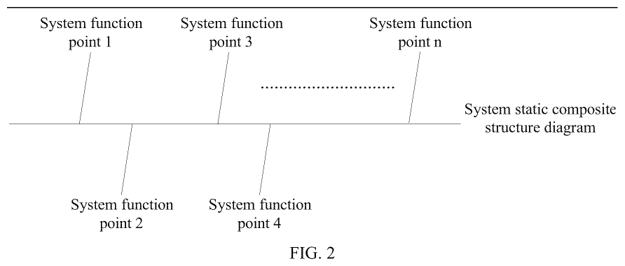

Referring to FIG. 2, the system-level static information consists of the system and system tasks to be accomplished by the system. The system name primitive is placed at the fishbone head as the endpoint of the transverse straight line, and the name primitives of the system tasks to be accomplished by the system are listed on the fishbone represented by the oblique line.

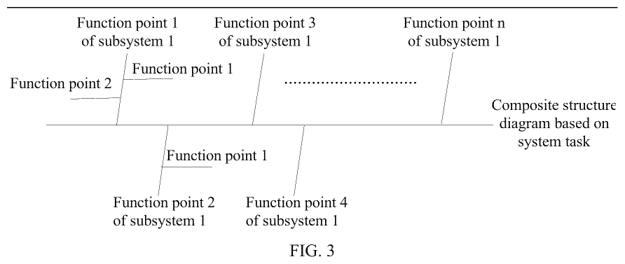

Referring to FIG. 3, the system-task-level static information consists of the system task to be accomplished by the system, and the various software and the function constituting the system. The system task name primitive is placed at the head of the fishbone as the endpoint of the transverse straight line, and the name primitive of the software required for the task and the name primitive for realizing a particular function are listed on the fishbone represented by the oblique line.

In an embodiment, the step (S30) includes the following steps.
(S31) The system task is represented by the arrowed transverse straight line. The system task name primitive is placed at the endpoint of the transverse straight line in the fishbone diagram as the fishbone head.
(S32) The software name primitive is listed on the oblique line in the corresponding fishbone diagram which uses the system task name primitive as the fishbone head.
(S33) The software function module name primitive is listed on the oblique line in the corresponding fishbone diagram in which the software name primitive is taken as the fishbone head.

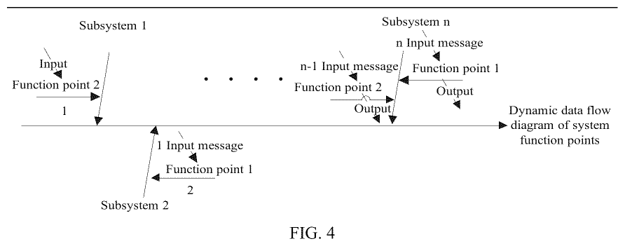

As shown in FIG. 4, based on the fishbone model, the system-task-level dynamic data flow is represented as the system function point dynamic data flow diagram. Specifically, the unified architecture of the system function point dynamic data flow diagram is as follows. The task to be accomplished by the system is represented by the transverse straight line with an arrow pointing from the left to the right. Each software of the system is represented by a transverse straight line with an arrow leading diagonally from the point on the transverse straight line with the arrow. Each software function module is represented by a segment with an arrow pointing diagonally to a point outside the segment of the software composing the system. The system task name primitive is placed at the fishbone head as the endpoint of the transverse straight line. The name primitive of the desired software is listed on the fishbone represented by the oblique line and headed by the system task name primitive. The software function module name primitive is listed on the fishbone represented by the oblique line and headed by the software name primitive.

In an embodiment, the sequential order of the system task name primitive, the software name primitive, and the software function module name primitive corresponds to the execution order of the system.

When the software or the software function module is in chronological juxtaposition, the arrowed transverse straight line connecting the software or the software function module is indicated by a dashed line.

It should be noted that the software name primitive connected by the dashed line or the software function module name primitive connected by the dashed line indicate a chronological juxtaposition relationship, i.e., the inputs and outputs of the function points are not sequential. For input and output messages between each software function module in the dynamic data flow diagram of the system task, and the output message between each software is indicated by numerical codes, while the final output of the system task is identified by the name of the output message. The input messages between each software are identified by “the numerical code of the associated output message+the name of the input message”, and the initial input of the system task is identified by the name of the input message.

In an embodiment, the step (S40) includes the following steps.

Based on the system task composite structure diagram, the static set Aₖ of the software function modules of the system is established, wherein k represents the number of the software function modules in the static set.

Based on the system function point dynamic data flow diagram, the dynamic set Aₙ of the software function modules of the system is established, wherein n represents the number of the software function modules in the dynamic set.

It should be noted that both k and n herein denote positive integers.

In an embodiment, the step (S50) includes the following steps.
(S51) According to the priority order of the software function modules in the static set, it is determined that the weight of each of the software function modules by using the weight determination model, expressed as:

$${\sum }_{i = 1}^{k} {m}_{i} = 1 ; and$$

$${m}_{i} ∈ {A}_{k} , and {m}_{1} > {m}_{2} > … > {m}_{k} .$$

In the above formula, Aₖ denotes a static set; m₁, m₂ . . . , and mₖ respectively denote the weights of the software function modules in the static set; and k denotes the number of the software function modules in the static set.

It is to be noted that the priority order of the software function modules therein is automatically or artificially ordered. The automatic ordering of the priority order can be understood to be that in the process of constructing the system task composite structure diagram, the diagram is constructed in accordance with the priority order of the software function modules. The software function modules with the high priority order are placed in the front, and the software function modules with the low priority order are placed in the back. The artificially ordering of the priority order can be that the priority order is determined by means of an expert assessment method. For example, according to the number of times that the software function module appears in each system task to determine the priority order of the software function module, the more times the software function module appears, the higher its priority order. Secondly, for the software function modules with the same number of appearance times, the priority order is determined according to the appearance order of the software function module. Specifically, if the software function module appears in different system task fishbone diagrams, which system task fishbone diagram appears first is determined to have a high priority order. If the software function module appears in the same system task fishbone diagram, the software function module that comes first in the chronological order is determined to have a high priority order.
(S52) The consistency adjustment is performed between the software function modules in the static set and the software function modules in the dynamic set based on the consistency determination model, expressed as:

$$Z = {\sum }_{i = 1}^{n} {m}_{i} ;$$

$${m}_{i} = {m}_{j}^{k} , {m}_{i} ∈ {A}_{k} , i \leq n , j \leq k ; and$$

$${m}_{i} = k , {m}_{i} ∉ {A}_{k} , i \leq n .$$

In the above formulas, n and k are positive integers; n denotes the number of the software function module in the dynamic set; and mⱼ^{k} denotes the weight of a corresponding software function module in the static set.

It should be noted that, for the software function modules in the dynamic set existing in the static set, i.e., mᵢ∈Aₖ and i≤n, the weight value m₁>m₂> . . . >mₖ, which is expressed as mⱼ^{k}, is assigned to each software realization module set in the static composition information. For the software function modules in the dynamic set that do not exist in the static set, the total number k of the software function modules in the static set is directly assigned as a penalty factor to the software function modules that exist in the dynamic set but not with the static set. The purpose of setting the penalty factor as the total number of software function modules is that, when the weighted sum is greater than 1, it means that there must be a function in the dynamic design that is not present in the static design. The extra function may bring the system greater risks such as failures, crashes, and must also bring the system redundancy, so the handling of the extra function must be paid attention, and it is necessary to analyze the extra functions in the dynamic design, to ensure the consistency of the system design.
(S53) When Z=1, it is determined that the software function modules in the static set are consistent with the software function modules in the dynamic set for system engineering level assessment.

It should be noted that when Z=1, it indicates that the system functional logic design is complete and consistent, and the system engineering level assessment can be conducted. After the assessment is passed, detailed design and implementation work of the system can be carried out.

In this embodiment, each function module in the static set is set with the weight value and compared with each function module in the dynamic set, so as to determine the consistency between each function module of the static design and each function module of the dynamic design. When the function module in the dynamic set has existed in the static function module set with weight value, then the dynamic function module is calibrated to the weight value given in the static set. If the function module in the dynamic set does not exist in the static function module set with weight value, then the function module in the dynamic set is calibrated to the total quantity value of the software function module in the static set.

In this way, the consistency and completeness of the two sets (dynamic set and static set) can be determined by the weighted sum. If the weighted sum is 1, it can be determined that the dynamic design function is consistent with the static design function and complete, and there is no redundant function or missing function. If the weighted sum is greater than 1, it can be concluded that there must be redundant function in the dynamic design function, and it is necessary to go back to the static design process for analyzing and finding the cause of the problem, and modifying the static design diagram or the dynamic design diagram until the weighted sum is 1. If the weighted sum is less than 1, it can be concluded that there must be a missing function in the dynamic design function, then it is necessary to go back to the static design process for analyzing and find the cause of the problem, and modifying the static design diagram or the dynamic design diagram until the weighted sum is 1.

In an embodiment, the step (S51) includes the following steps.

Based on the convergent normalization principle and the priority order, the weight of each of the software function modules in the static set is determined by decreasing the weights of the software function modules in the static set in a proportion of 1/k, expressed as:

$${m}_{1} = \frac{( k - 1 ) * {k}^{k - 1}}{{k}^{k} - 1} , i = 1 ; and$$

$${m}_{i} = {m}_{1} * \frac{1}{{k}^{i - 1}} , i \neq 1 , and i \leq k .$$

It should be noted that, in accordance with the convergence idea, the degree of criticality is decreased in the proportion of 1/k according to the priority order, that is, m₁ has the highest weight, the criticality factor value

$${m}_{1} = \frac{( k - 1 ) * {k}^{k - 1}}{{k}^{k} - 1} ;$$

mₖ has the lowest weight, the criticality factor value

$${m}_{k} = {m}_{1} * \frac{1}{{k}^{k - 1}} ;$$

and when mᵢ∈A, the calculation formula for the weight value of mᵢ is expressed as

$${m}_{i} = {m}_{1} * \frac{1}{{k}^{i - 1}} .$$

When k=1 is set, m₁=1.

It should be noted that at present, the usual consistency and integrity verification is judged by observing whether the dynamic execution of all state diagrams can reach an end state. This dynamic verification method increases the complexity of the operation when used. To achieve the effect of dynamic verification, it is necessary to do a lot of work, once the problems in the operation process rather than the design problems appear, which will lead to all the state diagrams cannot reach the end state, thereby brings difficulties for problem localization and troubleshooting. The advantage of adopting convergent normalization principle lies in accurately determining the consistency of dynamic design process set element and static design process set element. Moreover, the extra operations to be performed to build the dynamic execution is omitted, and the problems and impacts caused by building the dynamic execution operations are avoided. The workload of the designer is greatly reduced, and the work efficiency is improved.

In an embodiment, the method further includes the following steps.

When Z>1, the software function modules in the static set or the software function modules in the dynamic set are adjusted until Z≤1; and

When Z<1, the software function module in the static set or the software function module in the dynamic set are adjusted until Z=1.

It should be noted that when Z>1, it indicates that the logical design of the system function is unreasonable, i.e., the software function in the dynamic data flow information of each system function; the possible error point elements are given, i.e., elements in the set of Aₙ−{Aₙ∩Aₖ}, i.e., the information elements that appear only in the dynamic data flow information of each system function and do not appear in the static composition information of each system task. Manual processing is performed according to the dispute point. The dynamic data flow information of each system function or the static composition information of each system task is changed until Z≤1. When Z<1, it indicates that the logical design of the system function is unreasonable, i.e., the software function in the dynamic data flow information of each system function; the missing information element in the dynamic data flow information of each system function, i.e., the element in the set of Aₖ-Aₙ, i.e., the information elements that appear only in the static composition information of each system task and do not appear in the dynamic data flow information of each system function. Manual processing is performed according to the point of dispute to change the dynamic data flow information of each system function or the static composition information of each system task until Z=1.

The lightweight and generalized system engineering design method is provided in this embodiment. In this method, the system designer only needs to follow the method to build, based on the fishbone model, the static composite structure diagram of the system, the static composite structure diagram of the system function realizing the system, and the function point dynamic data flow diagram of the system in turn, which fits the development process and the design idea, and has not added extra work. In response to this problem, by combining the fishbone diagram often used in engineering as a carrier, its application meaning is adapted and its specific expressions and meanings are strictly defined, thereby realizing the fishbone-based model set applicable to various situations in system engineering design. The concept and understanding are made uniform, facilitating subsequent data processing. By means of the static analysis method, this disclosure can analyze inconsistencies and incompleteness without adding additional work, and reduce the workload by building, based on the fishbone model, the static composite structure diagram of the system, the static composite structure diagram of the system function realizing the system, and the function point dynamic data flow diagram of the system in turn. Moreover, the method in this embodiment can be used and implemented in the system engineering design process stage.

The system engineering design and verification method based on the fishbone model has the same application scenarios as MBSE, which is illustrated below by two specific examples, namely the design of link communication system engineering and the design of a parking access control system, where the design and verification process includes the following steps.

### EXAMPLE 1

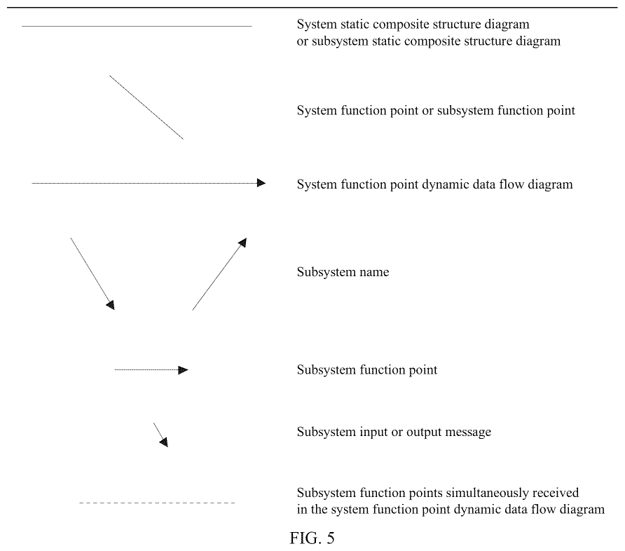

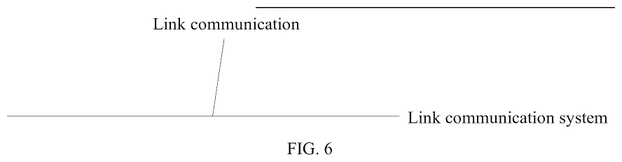

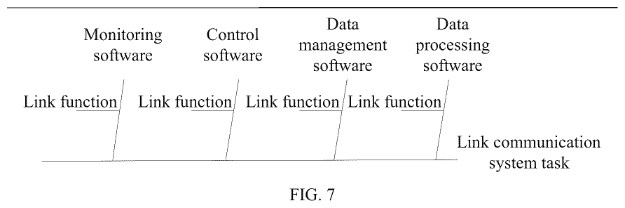

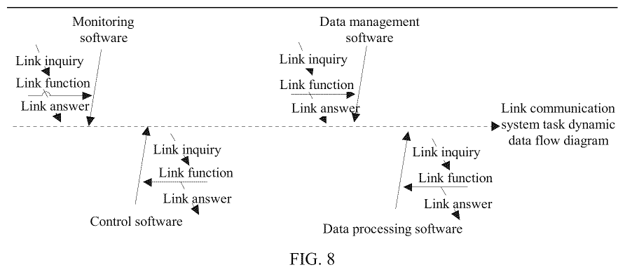

(1) On the self-development tool, the link communication system-level static composite structure schematic diagram is constructed as shown in FIG. 6; and the schematic diagram of the set of icon prescribed meanings is shown in FIG. 5. The link communication system consists of link communication tasks. The system name (i.e., link communication system) is placed at the head of the fish bone as the endpoint of the transverse straight line. The system task name (link communication function) is listed on the fishbone represented by the oblique line. Specifically, the system name icon is represented by the transverse straight line. The system task name icon is represented by the oblique line attached to the transverse straight line of the system name icon.
(2) On the self-development tool, the static composite structure schematic diagram of the link communication system task is constructed, as shown in FIG. 7. The link communication system task diagram consists of each software and software function that realizes this system task. The link communication system task name is placed at the head of the fish bone as the endpoint of the transverse straight line. The name of each software and the name of each software function that realizes the system task are listed on the fish bone indicated by the oblique line. The link communication system task composite structure diagram consists of the name of each software and the name of each software function point. The software includes the monitoring software, the data management software, the control software, and the data processing software. The software functions include the link function of the monitoring software, the link function of the data management software, the link function of the control software, and the link function of the data processing software. The link communication system task name is placed at the head of the fishbone as the endpoint of the transverse straight line; and the software function point name is listed on the fishbone represented by the oblique line.
(3) On the self-development tool, the dynamic data flow schematic diagram of the link communication system task is constructed as shown in FIG. 8. The dynamic data flow schematic diagram of the link communication system task includes the name of the system task (link communication system task), the name of each software, the name of the software function point, and the inputs and outputs of the software function point. The software includes the monitoring software, the data management software, the control software, and the data processing software. The inputs and outputs of the software function point include monitoring software input: link query; data management software input: link query; control software input: link query; and signal processing software input: link query; and monitoring software output: link answer; data management software output: link answer; control software output: link answer; and signal processing software output: link answer. The system task name icon is represented by the transverse straight line with an arrow pointing from left to right. Each software name icon is represented by the line segment leading diagonally from the point on the line. The software function point name icon is represented by the arrowed line segment formed by leading from the point on the arrowed line segment of each software name icon to each software name icon. The software function point input icon is represented by the line segment with the arrow leading to the software function point name icon. The software function point output icon is represented by the arrowed line segment leading to the software function point name icon. In addition, the dashed line in the straight line representing the system task name icon indicates that the software function points connected on the dashed line are in a chronological juxtaposition, i.e., the inputs and outputs of their function points are not sequential.
(4) According to the extracted static composition information of the system task, it automatically completes the priority order of each software realization module, and establishes the weight setting of each software realization module according to the priority order. Specifically, according to the established static composition information of each system task, the automatic priority order realization method of each software module establishes each system software function module static set A₄={link function of the monitoring software, link function of the control software, link function of the data management software, and link function of the data processing software}. Because each software function point has the same number of occurrences in the fishbone model, the priority order of the software functions is determined according to their order of occurrence, and the weights of each software function point are obtained: m_{link function of the monitoring software}=192/255, m_{link function of the control software}=48/255, m_{link function of the data management software}=12/255, and m_{link function of the data processing software}=3/255.
(5) Based on the extracted dynamic data flow information of each system function, the logical correctness determination is performed. In accordance with the principles of mᵢ=mⱼ^{k}, mᵢ∈Aₖ, i≤n, j≤k, and mᵢ=k mᵢ∉Aₖ,

$$i \leq n , Z = {\sum }_{i = 1}^{n} {m}_{i}$$

is performed. The weight value of the system function according to the dynamic data flow information of each system function is accumulated, and the value is Z=1. Therefore, the integrity and consistency requirements are satisfied between the system function and the various software realizing the system tasks, and the system design is logically reasonable, and the scope of influence is controllable.

### EXAMPLE 2

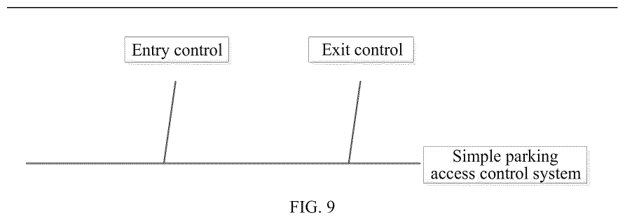

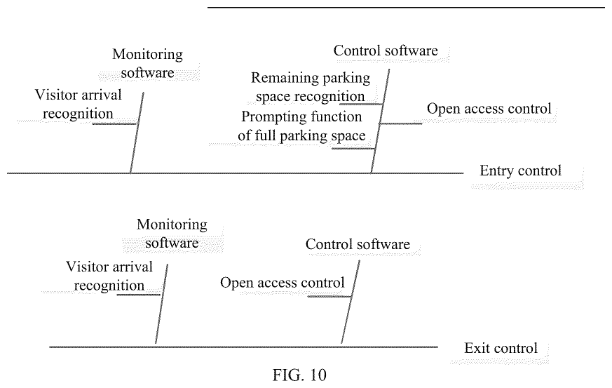

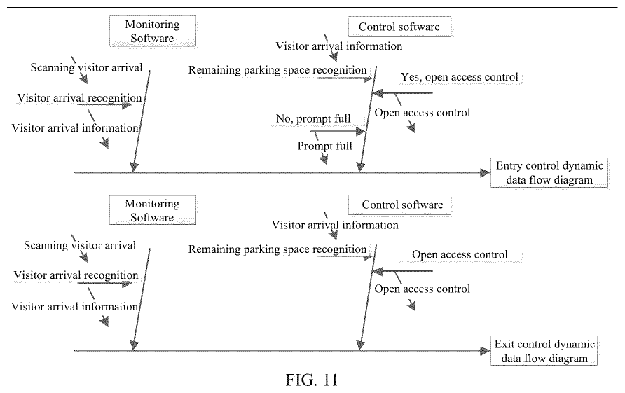

Regarding to the parking access control system, and the design and verification steps are as follows.
(1) On the self-development tool, the schematic diagram of the static composite structure of the parking access control system is constructed as shown in FIG. 9. The parking access control system consists of entry control and exit control. The system name (i.e., parking access control system) is placed in the head of the fishbone as the endpoint of the transverse straight line. The system task name (entry control function and exit control function) is listed on the fishbone indicated by the oblique line. The system name icon is indicated by a transverse straight line. The system task name icon is indicated by the oblique line connected to the transverse straight line of the system name icon.
(2) On the self-development tool, the schematic diagram of the static composite structure of the parking access control system task is constructed, as shown in FIG. 10. The entry control system task diagram consists of each software and software function that realizes the system task. The entry control system task name is placed at the head of the fishbone as the endpoint of the transverse straight line. Each software name and software function name that realizes the system task are listed on the fishbone indicated by the oblique line. The entry control system task composite structure diagram consists of each software name (monitoring software and control software) and software function point name (visitor arrival recognition function, open access control function, and prompting function of full parking space). The entry control system task name is placed at the head of the fishbone as the endpoint of the transverse straight line. The software function point name is listed on the fishbone indicated by the oblique line segment. The task structure diagram of the exit control system consists of the software names (monitoring software and control software) and the software function point names (visitor arrival recognition function and open access control function). The exit control system task names are placed at the head of the fishbone as the endpoint of the transverse straight line. The software function point names are listed on the fishbone represented by the oblique line segment.
(3) On the self-development tool, the schematic diagram of the dynamic data flow of the parking access control system task is shown in FIG. 11. The dynamic data flow name icons of the parking access control system tasks include the system task name, the software name, the software function point name, and the software function point inputs and outputs. The system tasks include the entry control system task and the exit control system task. The software includes monitoring software and control software. The software functions include visitor arrival recognition function, open access control function, and prompting function of full parking space. The software function point inputs and outputs include monitoring software input: scanning visitor arrival; control software input: visitor arrival information; and monitoring software output: visitor arrival information; control software output: open access control or prompt full.

The system task name icon is represented by the transverse straight line with an arrow pointing from left to right. Each software name icon is represented by the line segment leading diagonally from the point on the line. The software function point name icon is represented by the arrowed line segment formed by leading from the point on the arrowed line segment of each software name icon to each software name icon. The software function point input icon is represented by the line segment with the arrow leading to the software function point name icon. The software function point output icon is represented by the arrowed line segment leading to the software function point name icon. In addition, the dashed line in the straight line representing the system task name icon indicates that the software function points connected on the dashed line are in a chronological juxtaposition, i.e., the inputs and outputs of their function points are not sequential.
(4) According to the extracted static composition information of the system task, it automatically completes the priority order of each software realization module, and establishes the weight setting of each software realization module according to the priority order. Specifically, according to the established static composition information of each system task, the automatic priority order realization method of each software module establishes each system software function module static set A₄={visitor arrival recognition function of monitoring software; remaining parking space recognition function of control software; open access control function of the control software when there is remaining space; prompting function of full parking space; open access control function of the control software}. Because each software function point has the same number of occurrences in the fishbone model, the priority order of the software functions is determined according to their order of occurrence, and the weights of each software function point are obtained: m_{visitor arrival recognition function of monitoring software}=2500/3 124; m_{remaining parking space recognition function of control software}=500/3124; m_{open access control function of control software when there is remaining space}=100/3124; m_{prompting function of full parking space}=20/3 124; m_{open access control function of control software}=4/3124.
(5) Based on the extracted dynamic data flow information of each system function, the logical correctness determination is performed. In accordance with the principles of mᵢ=mⱼ^{k}, mᵢ∈Aₖ, i≤n, j≤k, and mᵢ=k, mᵢ∉Aₖ, i≤n,

$$Z = {\sum }_{i = 1}^{n} {m}_{i}$$

is performed. The weight value of the system function according to the dynamic data flow information of each system function is accumulated, and the value is Z=1. Therefore, the integrity and consistency requirements are satisfied between the system function and the various software realizing the system tasks, and the system design is logically reasonable, and the scope of influence is controllable.

This example resolves the arbitrariness of the retrospective correlation between the system and the software for realizing the system tasks, and ensures the completeness and consistency between the system function and the software for realizing the system task through the dynamic data flow analysis based on the system task, the static composite structure analysis of the system task, and the static composite structure analysis of the system. By comparing the dynamic data flow of each system function based on the fishbone model with the static composite structure diagram of each system function, this example can effectively verify the design of the system and the software realizing the system, ensure the rigor and non-duality of the design, and have a reasonable structure, which is easy to maintain and upgrade in the future.

Moreover, the method for designing and verifying the system engineering based on fishbone model solves the learning threshold of the existing MBSE method, making it easier for engineers to get started, understand and use. The fishbone model-based static composite diagram of the system function, the static composite diagram of each system function, and the fishbone model-based dynamic data flow diagram of the system function point can make the structure of the system simple and clear, virtualize the actual system, simulate the use scenarios, and validate the logic and impact of the system design, which helps to expose and discover the system's design problems early.

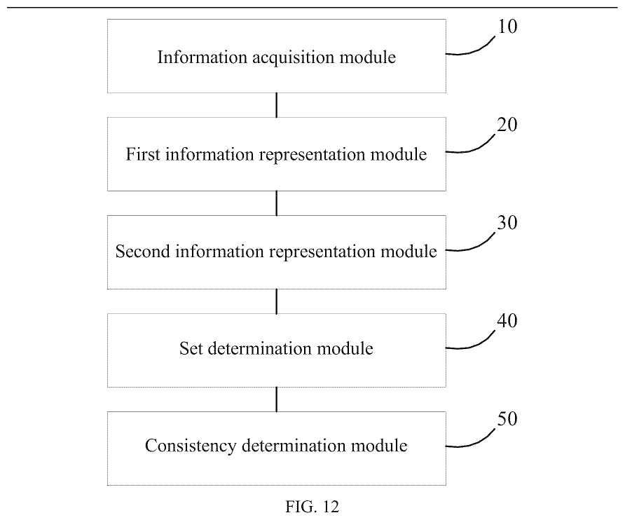

Referring to FIG. 12, the disclosure also proposes a system for designing and verifying the system engineering based on fishbone model, including an information acquisition module 10, a first information representation module 20, a second information representation module 30, a set determination module 40, and a consistency determination module 50.

The information acquisition module 10 is configured for acquiring modeling information. The modeling information includes the system-level static information, the system-task-level static information, and the system-task-level dynamic data flow.

The first information representation module 20 is configured for representing, based on the fishbone diagram analysis, the system-level static information as the system static composite structure diagram, and representing the system-task-level static information as the system task composite structure diagram corresponding to each system task in the system static composite structure diagram.

The second information representation module 30 is configured for representing the system-task-level dynamic data flow as the system function point dynamic data flow diagram based on the fishbone diagram analysis.

The set determination module 40 is configured for establishing the static set of software function modules of the system based on the system task composite structure diagram; and establishing the dynamic set of software function modules of the system based on the system function point dynamic data flow diagram.

The consistency determination module 50 is configured for performing the consistency adjustment between the software function modules in the static set and the software function modules in the dynamic set to make the software function modules in the static set consistent with the software function modules in the dynamic set.

In an embodiment, the modeling information obtained by the information acquisition module 10 is as follows.

The system-level static information includes the system name primitive and the system task primitive.

The system-task-level static information includes the system task name primitive and the software function module name primitive.

The system-task-level dynamic data flow includes the system task name primitive, the software name primitive, and the software function module name primitive.

In an embodiment, the first information representation module 20 includes a system static composite representation unit and a system task composition representation unit.

The system static composite representation unit is used for placing the system name primitive at the endpoint of the transverse straight line in the fishbone diagram as the fishbone head, and placing the system task name primitive on the oblique line of the fishbone diagram, so as to form the system static composite structure diagram.

The system task composite representation unit is used for, for the system task in the system static composite structure diagram, placing the system task name primitive at the endpoint of the transverse straight line in the fishbone diagram as the fishbone head, and placing the software function module name primitive for performing the system task on the oblique line of the fishbone diagram, so as to form the system task composite structure diagram.

In an embodiment, the second information representation module 30 includes a first representation unit, a second representation unit, and a third representation unit.

The first representation unit is configured for representing the system task with the arrowed transverse straight line; and placing the system task name primitive at the endpoint of the transverse straight line in the fishbone diagram as the fishbone head.

The second representation unit is configured for listing the software name primitive on the oblique line in the corresponding fishbone diagram in which the system task name primitive is taken as the fishbone head.

The third representation unit is configured for listing the software function module name primitive on the oblique line in the corresponding fishbone diagram in which the software name primitive is taken as the fishbone head.

In an embodiment, the order of the system task name primitive, the software name primitive, and the software function module name primitive is consistent with the execution order of the system.

When the software or the software function module is in chronological juxtaposition, the arrowed transverse straight line connecting the software or the software function module is indicated by a dashed line.

It should be noted that the software name primitives connected by the dashed line or the software function module name primitives connected by the dashed line indicate a chronological juxtaposition relationship, i.e., the inputs and outputs of the function points are not sequential. For the input and output messages between each software function module in the dynamic data flow diagram of the system task, the output message between each software is indicated by numerical codes, while the final output of the system task is identified by the name of the output message. The input messages between each software are identified by “the numerical code of the associated output message+the name of the input message”, and the initial input of the system task is identified by the name of the input message.

In an embodiment, the set determination module 40 includes a static set determination unit and a dynamic set determination unit.

The static set determination unit is configured for establishing the static set Aₖ of the software function modules of the system based on the system task composite structure diagram, wherein k represents the number of the software function modules in the static set.

The dynamic set determination unit is configured for establishing the dynamic set Aₙ of the software function modules of the system based on the system function point dynamic data flow diagram, wherein n represents the number of the software function modules in the dynamic set.

In an embodiment, the consistency determination module 50 includes a weight assignment module.

The weight assignment module for, according to the priority order of the software function modules in the static set, determining the weight of each of the software function modules by using the weight determination model which is expressed as:

$${\sum }_{i = 1}^{k} {m}_{i} = 1 ; and$$

$${m}_{i} ∈ {A}_{k} , and {m}_{1} > {m}_{2} > … > {m}_{k} .$$

In above formula, Aₖ denotes the static set; m₁, m₂ . . . , and mₖ respectively denotes the weights of the software function modules in the static set; and k denotes the number of the software function modules in the static set.

In this embodiment, each function module in the static set is set with the weight value and compared with each function module in the dynamic set, to determine the consistency between each function module of the static design and each function module of the dynamic design. When the function module in the dynamic set has existed in the static function module set with weight value, then the dynamic function module is calibrated to the weight value given in the static set. If the function module in the dynamic set does not exist in the static function module set with weight value, then the function module in the dynamic set is calibrated to the total quantity value of the software function module in the static set.

In this way, the consistency and completeness of the two sets (dynamic set and static set) can be determined by the weighted sum. If the weighted sum is 1, it can be determined that the dynamic design function is consistent with the static design function and complete, and there is no redundant function or missing function. If the weighted sum is greater than 1, it can be concluded that there must be redundant function in the dynamic design function, and it is necessary to go back to the static design process for analyzing and finding the cause of the problem, and modifying the static design diagram or the dynamic design diagram until the weighted sum is 1. If the weighted sum is less than 1, it can be concluded that there must be a missing function in the dynamic design function, then it is necessary to go back to the static design process for analyzing and find the cause of the problem, and modifying the static design diagram or the dynamic design diagram until the weighted sum is 1.

It is to be noted that the priority order of the software function modules therein is automatically or artificially ordered. The automatic ordering of the priority order can be understood to be that in the process of constructing the system task composite structure diagram, the diagram is constructed in accordance with the priority order of the software function modules. The software function modules with the high priority order are placed in the front, and the software function modules with the low priority order are placed in the back. The artificially ordering of the priority order can be that the priority order is determined by means of an expert assessment method. For example, according to the number of times that the software function module appears in each system task to determine the priority order of the software function module, the more times the software function module appears, the higher its priority order. Secondly, for the software function modules with the same number of appearance times, the priority order is determined according to the appearance order of the software function module. Specifically, if the software function module appears in different system task fishbone diagrams, which system task fishbone diagram appears first is determined to have a high priority. If the software function module appears in the same system task fishbone diagram, the software function module that comes first in the chronological order is determined to have a high priority.

The consistency determination unit is configured for performing consistency adjustment between the software function modules in the static set and the software function modules in the dynamic set based on the consistency determination model which is expressed as:

$$Z = {\sum }_{i = 1}^{n} {m}_{i} ;$$

$${m}_{i} = {m}_{j}^{k} , {m}_{i} ∈ {A}_{k} , i \leq n , j \leq k ; and$$

$${m}_{i} = k , {m}_{i} ∉ {A}_{k} , i \leq n .$$

In the above formulas, n and k are positive integers; n denotes the number of the software function module in the dynamic set; and mⱼ^{k} denotes the weight of the corresponding software function module in the static set.

It should be noted that, for the software function modules in the dynamic set existing in the static set, i.e., mᵢ∈Aₖ and i≤n, the weight value m₁>m₂> . . . >mₖ, which is expressed as mⱼ^{k}, is assigned to each software realization module set in the static composition information. For the software function modules in the dynamic set that do not exist in the static set, the total number k of the software function modules in the static set is directly assigned as a penalty factor to the software function modules that exist in the dynamic set but not with the static set. The purpose of setting the penalty factor as the total number of software function modules is that, when the weighted sum is greater than 1, it means that there must be a function in the dynamic design that is not present in the static design. The extra function may bring the system greater risks such as failures, crashes, and must also bring the system redundancy, so the handling of the extra function must be paid attention, and it is necessary to analyze the extra functions in the dynamic design, to ensure the consistency of the system design.

The determination unit is configured for determining that the software function modules in the static set are consistent with the software function modules in the dynamic set, when Z=1, for system engineering level assessment.

It should be noted that when Z=1, it indicates that the system functional logic design is complete and consistent, and the system engineering level assessment can be conducted, and after the review is passed, detailed design and implementation work of the system can be carried out.

In an embodiment, the weight assignment unit is configured for, based on the convergent normalization principle and the priority order, the weight of each of the software function modules in the static set is determined by decreasing weights of the software function modules in the static set in a proportion of 1/k, expressed as:

$${m}_{1} = \frac{( k - 1 ) * {k}^{k - 1}}{{k}^{k} - 1} , i = 1 ; and$$

$${m}_{i} = {m}_{1} * \frac{1}{{k}^{i - 1}} , i \neq 1 , and i \leq k .$$

It should be noted that, in accordance with the convergence idea, the degree of criticality is decreased in the proportion of 1/k according to the priority order, that is, m₁ has the highest weight, the criticality factor value

$${m}_{1} = \frac{( k - 1 ) * {k}^{k - 1}}{{k}^{k} - 1} ;$$

mₖ has the lowest weight, the criticality factor value

$${m}_{k} = {m}_{1} * \frac{1}{{k}^{k - 1}} ;$$

and when mᵢ∈A, the calculation formula for the weight value of mᵢ is expressed as

$${m}_{i} = {m}_{1} * \frac{1}{{k}^{i - 1}} .$$

When k=1 is set, m₁=1.

It should be noted that at present, the usual consistency and integrity verification is judged by observing whether the dynamic execution of all state diagrams can reach an end state. This dynamic verification method increases the complexity of the operation when used. To achieve the effect of dynamic verification, it is necessary to do a lot of work, once the problems in the operation process rather than the design problems appear, which will lead to all the state diagrams cannot reach the end state, thereby brings difficulties for problem localization and troubleshooting. The advantage of adopting convergent normalization idea lies in accurately determining the consistency of dynamic design process set element and static design process set element. Moreover, the extra operations to be performed to build the dynamic execution is omitted, and the problems and impacts caused by building the dynamic execution operations are avoided. The workload of the designer is greatly reduced, and the work efficiency is improved.

In an embodiment, the system further includes an adjustment module.

The adjustment module is configured for, when Z>1, adjusting the software function modules in the static set or the software function modules in the dynamic set until Z≤1; and at Z<1, adjusting the software function modules in the static set and the software function modules in the dynamic set until Z=1.

It should be noted that when Z>1, it indicates that the logical design of the system function is unreasonable, i.e., the software function in the dynamic data flow information of each system function; the possible error point elements are given, i.e., elements in the set of Aₙ−{Aₙ∩Aₖ}, i.e., the information elements that appear only in the dynamic data flow information of each system function and do not appear in the static composition information of each system task. Manual processing is performed according to the point of dispute. The dynamic data flow information of each system function or the static composition information of each system task is changed until Z≤1. When Z<1, it indicates that the logical design of the system function is unreasonable, i.e., the software function in the dynamic data flow information of each system function; the missing information element in the dynamic data flow information of each system function, i.e., the element in the set of Aₖ-Aₙ, i.e., the information elements that appear only in the static composition information of each system task and do not appear in the dynamic data flow information of each system function. Manual processing is performed according to the point of dispute to change the dynamic data flow information of each system function or the static composition information of each system task until Z=1.

It is to be noted that other embodiments or implementation method of the systems engineering design and verification system based on the fishbone model described in the present disclosure can be referred to each of the above-mentioned method embodiments and will not be repeated herein.

In the disclosure, the terms “an embodiment”, “some embodiments”, “examples”, “specific examples”, “some examples”, mean that the specific features, structures, materials, or characteristics described in conjunction with the embodiment or example are included in at least one embodiment or example of the present disclosure. In this disclosure, schematic expressions of the above terms do not necessarily refer to the same embodiment or example. Moreover, the specific features, structures, materials, or characteristics described may be combined in any one or more embodiments or examples in a suitable manner.

Furthermore, the terms “first” and “second” are merely descriptive, and cannot be understood as indicating or implying relative importance or implying the number of technical features. Thus, a feature defined with the terms “first”, “second” may explicitly or implicitly include at least one such feature. In the disclosure, “plurality” means at least two, e.g., two, three, etc., otherwise expressly specified.

The embodiments above are merely illustrative, and not intended to limit the scope of the disclosure. It should be understood that any modifications and replacements made by those skilled in the art without departing from the spirit of the disclosure should fall within the scope of the disclosure defined by the appended claims.

What is claimed is:

1. A method for designing and verifying a system engineering based on fishbone model, comprising:
acquiring modeling information, wherein the modeling information comprises system-level static information, system-task-level static information, and system-task-level dynamic data flow;
based on fishbone diagram analysis, representing the system-level static information as a system static composite structure diagram, and representing the system-task-level static information as a system task composite structure diagram corresponding to each system task in the system static composite structure diagram;
based on the fishbone diagram analysis, representing the system-task-level dynamic data flow as a system function point dynamic data flow diagram;
based on the system task composite structure diagram, establishing a static set of first software function modules of a system; and based on the system function point dynamic data flow diagram, establishing a dynamic set of second software function modules of the system; and
performing a consistency adjustment between the first software function modules in the static set and the second software function modules in the dynamic set to make the first software function modules in the static set consistent with the second software function modules in the dynamic set.

2. The method of claim 1, wherein the system-level static information comprises a system name primitive and a system task name primitive;
the system-task-level static information comprises the system task name primitive and a software function module name primitive; and
the system-task-level dynamic data flow comprises the system task name primitive, a software name primitive and the software function module name primitive.

3. The method of claim 2, wherein the step of “based on fishbone diagram analysis, representing the system-level static information as a system static composite structure diagram, and representing the system-task-level static information as a system task composite structure diagram corresponding to each system task in the system static composite structure diagram” comprises:
placing the system name primitive at an endpoint of a transverse straight line in a first fishbone diagram as a fishbone head, and placing the system task name primitive on an oblique line of the first fishbone diagram, so as to form the system static composite structure diagram; and
for a system task in the system static composite structure diagram, placing the system task name primitive at an endpoint of a transverse straight line in a second fishbone diagram as a fishbone head, and placing the software function module name primitive for performing the system task on an oblique line of the second fishbone diagram, so as to form the system task composite structure diagram.

4. The method of claim 1, wherein the step of “based on the fishbone diagram analysis, representing the system-task-level dynamic data flow as a system function point dynamic data flow diagram” comprises:
representing a system task by an arrowed transverse straight line; and placing a system task name primitive at an endpoint of a transverse straight line in a first fishbone diagram as a fishbone head;
placing a software name primitive on an oblique line in the first fishbone diagram; and
placing a software function module name primitive on an oblique line in a second fishbone diagram in which the software name primitive is taken as the fishbone head.

5. The method of claim 4, wherein an order of the system task name primitive, the software name primitive, and the software function module name primitive is consistent with an execution order of the system; and
when a software or a software function module is in chronological juxtaposition, the arrowed transverse straight line connecting the software or the software function module is indicated by a dashed line.

6. The method of claim 1, wherein the step of “based on the system task composite structure diagram, establishing a static set of first software function modules of a system; and based on the system function point dynamic data flow diagram, establishing a dynamic set of second software function modules of the system” comprises:
establishing a static set Aₖ of the first software function modules of the system based on the system task composite structure diagram, wherein k represents the number of the first software function modules in the static set; and
establishing a dynamic set Aₙ of the second software function modules of the system based on the system function point dynamic data flow diagram, wherein n represents the number of the second software function modules in the dynamic set.

7. The method of claim 1, wherein the step of “performing a consistency adjustment between the first software function modules in the static set and the second software function modules in the dynamic set to make the first software function modules in the static set consistent with the second software function modules in the dynamic set” comprises:
according to a priority order of the first software function modules in the static set, determining a weight of each of the first software function modules by using a weight determination model, expressed as:
$${\sum }_{i = 1}^{k} {m}_{i} = 1 ; and$$
$${m}_{i} ∈ {A}_{k} , and {m}_{1} > {m}_{2} > … > {m}_{k} ;$$
wherein Aₖ denotes the static set; m₁, m₂ . . . , and mₖ respectively denote weights of the first software function modules in the static set; and k denotes the number of the first software function modules in the static set;
performing the consistency adjustment between the first software function modules in the static set and the second software function modules in the dynamic set based on a consistency determination model, expressed as:
$$Z = {\sum }_{i = 1}^{n} {m}_{i} ;$$
$${m}_{i} = {m}_{j}^{k} , {m}_{i} ∈ {A}_{k} , i \leq n , j \leq k ; and$$
$${m}_{i} = k , {m}_{i} ∉ {A}_{k} , i \leq n ;$$
wherein n and k are positive integers; n denotes the number of the second software function modules in the dynamic set; and mⱼ^{k} denotes a weight of a corresponding first software function module in the static set; and
when Z=1, it is determined that the first software function modules in the static set are consistent with the second software function modules in the dynamic set for system engineering level assessment.

8. The method of claim 7, wherein the step of “according to a priority order of the first software function modules in the static set, determining a weight of each of the first software function modules by a weight determination model” comprises:
based on a convergence principle and the priority order, determining the weight of each of the first software function modules by decreasing weights of the first software function modules in the static set in a proportion of 1/k, expressed as:
$${m}_{1} = \frac{( k - 1 ) * {k}^{k - 1}}{{k}^{k} - 1} , i = 1 ; and$$
$${m}_{i} = {m}_{1} * \frac{1}{{k}^{i - 1}} , i \neq 1 , and i \leq k .$$

9. The method of claim 7, wherein when Z>1, the first software function modules in the static set or the second software function modules in the dynamic set are adjusted until Z≤1; and
when Z<1, the first software function modules in the static set or the second software function modules in the dynamic set are adjusted until Z=1.

10. A system for designing and verifying a system engineering based on fishbone model, comprising:
an information acquisition module;
a first information representation module;
a second information representation module;
a set determination module; and
a consistency determination module;
wherein the information acquisition module is configured for acquiring modeling information, wherein the modeling information comprises system-level static information, system-task-level static information, and system-task-level dynamic data flow;
the first information representation module is configured for representing, based on fishbone diagram analysis, the system-level static information as a system static composite structure diagram, and representing the system-task-level static information as a system task composite structure diagram corresponding to each system task in the system static composite structure diagram;
the second information representation module is configured for representing the system-task-level dynamic data flow as a system function point dynamic data flow diagram based on the fishbone diagram analysis;
the set determination module is configured for establishing a static set of first software function modules of a system based on the system task composite structure diagram; and establishing a dynamic set of second software function modules of the system based on the system function point dynamic data flow diagram; and
the consistency determination module is configured for performing a consistency adjustment between the first software function modules in the static set and the second software function modules in the dynamic set to make the first software function modules in the static set consistent with the second software function modules in the dynamic set.
